(19) United States
(12) Patent Application Publication
(10) Pub. No.: US 2024/0056044 A1
(43) Pub. Date: Feb. 15, 2024

(54) PRECISION OPERATIONAL AMPLIFIER USING FLOATING INPUT STAGE

(71) Applicant: SEMICONDUCTOR COMPONENTS INDUSTRIES, LLC, Scottsdale, AZ (US)

(72) Inventor: Catalin Ionut PETROIANU, Bucharest (RO)

(73) Assignee: SEMICONDUCTOR COMPONENTS INDUSTRIES, LLC, Scottsdale, AZ (US)

(21) Appl. No.: 18/259,383

(22) PCT Filed: Feb. 3, 2022
(86) PCT No.: PCT/US2022/070504

§ 371 Date: Jun. 26, 2023

Related U.S. Application Data
(60) Provisional application No. 63/199,945, filed on Feb. 4, 2021.

(51) Int. Cl. H03F 3/45; H03G 3/32; H03F 1/26

(52) U.S. Cl. CPC H03F 3/45968; H03F 3/45475; H03G 3/32; H03F 3/45273; H03F 1/26; H03F 2200/297

(57) ABSTRACT

The operational amplifier disclosed includes an input stage configured to receive power from a floating supply circuit in in a low voltage range that can float according to the common mode voltage at the input. The low voltage supply facilitates the use of low voltage components that can improve the precision of the operational amplifier by lowering the offset voltage. The input stage utilizes a first gain block and a second gain block. The first gain block is configured to have a low offset voltage while the second gain h block is configured to have a high gain. Dividing these aspects over separate gain blocks improves the precision and noise performance of the operational amplifier. The operational amplifier has high gain at low frequencies and at high frequencies due to a topology that combines a low gain, high bandwidth path with a high gain, low bandwidth path at the output.

### CROSS-REFERENCE TO RELATED APPLICATION

This application claims the benefit of U.S. Provisional Application No. 63/199,945, filed on Feb. 4, 2021, which is hereby incorporated by reference in its entirety.

### FIELD OF THE DISCLOSURE

The present disclosure relates to analog microelectronics and more specifically to an operational amplifier having a low offset voltage and suitable for a wide range of common mode voltages and supply voltages due to its floating input stage.

### BACKGROUND

The precision of operational amplifiers may be negatively affected by offset voltage. Offset voltage is a small voltage that appears at the output of an operational amplifier when zero volts is expected, such as when the inputs are equal voltage. The offset voltage can be due to mismatches in differential circuits, such as a differential pair. The mismatches may be between fabricated transistor elements (i.e., fingers) included within a single transistor or may be between a pair of different transistors in a differential pair. Increasing a physical device size (i.e., die area) of a transistor may be used to minimize mismatches and therefore reduce an offset voltage on average for the operational amplifier in production. Accordingly, a desire for high precision (i.e., low offset voltage) may contrast with a desire for small size. This contrast may be enhanced when high-voltage operation is desired because larger device sizes are required to handle the high-voltages. Chopping or trimming techniques may be used to reduce offset voltage but these techniques can add cost and complexity to an operational amplifier and therefore may not be suitable for some applications.

### SUMMARY

In at least one aspect, the present disclosure generally describes an operational amplifier including an input stage and a floating supply. The input stage includes a first gain block (G1) including a first low voltage (LV) differential pair having a first voltage offset and a first gain. The input stage further includes a second gain block (G2) including a second LV differential pair having a second voltage offset and a second gain. The first voltage offset of the input stage is less than the second voltage offset. Additionally, the second gain of the input stage is greater than the first gain. The floating supply is powered by a supply voltage ranging from an upper rail voltage (VDD) to a lower rail voltage (VSS). The floating supply is configured to output a floating supply voltage ranging from a positive voltage (FP) to a negative voltage (FN), where the floating supply (i) floats according to an input (voltage) of the operational amplifier and (ii) provides power to the input stage. The operational amplifier may be implemented according to any combination of the following possible implementations.

In a first possible implementation, the first LV differential pair and the second LV differential pair are isolated from the upper rail voltage (VDD) and the lower rail voltage (VSS) by the floating supply.

In a second possible implementation, the floating supply receives the positive voltage (FP) from an upper common node of the first gain block (G1) and generates a negative voltage (FN) at a lower common node of the first gain block (G1) and the second gain block (G2).

In a third possible implementation, the first gain block (G1) includes a first LV transistor coupled at its gate to a positive input (INP) of the operational amplifier and a second LV transistor coupled at its gate to a negative input (INN) of the operational amplifier. A source of the first LV transistor and a source of the second LV transistor are directly connected to the upper common node. The first gain block (G1) further includes a first resistor coupled between a drain of the first LV transistor and the lower common node, where the drain is a positive output of the first gain block (G1_OUTP). The first gain block (G1) further includes a second resistor coupled between a drain of the second LV transistor and the lower common node, where the drain is a negative output of the first gain block (G1_OUTN). The first gain block (G1) further includes a first upper current source coupled between the upper rail voltage (VDD) and the upper common mode.

In a fourth possible implementation, the positive voltage (FP) at the upper common node of the first gain block (G1) is the lower of the positive input (INP) and the negative input (INN) plus a gate to source voltage (VGS) of the first LV transistor or the second LV transistor.

In a fifth possible implementation of the operational amplifier, the second gain block (G2) includes a third LV transistor coupled at its gate to a negative output of the first gain block (G1_OUTN) and a fourth LV transistor coupled at its gate to a positive output of the first gain block (G1_OUTP). A source of the fourth LV transistor is directly coupled to a source of the third transistor at a common source node. The second gain block (G2) further includes a second upper current source that is coupled between the upper rail voltage (VDD) and the common source node. The second gain block (G2) further includes an active load that is coupled between a drain of the third LV transistor and the lower common node and between a drain of the fourth LV transistor and the lower common node. A negative output of the second gain block (G2_OUTN) is the drain of the third LV transistor, while a positive output of the second gain block (G2_OUTP) is the drain of the fourth LV transistor.

In a sixth possible implementation of the operational amplifier the floating supply includes an input transistor that is coupled at its gate to the upper common node of the first gain block (G1) to receive the positive voltage (FP) and coupled at its drain to the upper rail voltage (VDD) via a bias resistor. The floating supply further includes a voltage source that is coupled between a source of the input transistor and the lower common node to generate the negative voltage (FN) at the lower common node of the first gain block (G1) and the second gain block (G2). The floating supply further includes a lower current source coupled between the lower common node and the lower rail voltage (VSS).

In a seventh possible implementation, the floating supply further includes an amplifier configured to compare a voltage, which corresponds to the positive voltage (FP), to a reference voltage (VREF), which corresponds to a threshold voltage of the input transistor. The floating supply further includes a clamping transistor coupled between the lower common node and the lower rail voltage (VSS). The clamping transistor is controlled by the amplifier so that when the voltage drops below the reference voltage (VREF), the negative voltage (FN) is coupled (e.g., shorted) to the lower rail voltage (VSS).

In an eighth possible implementation, the operational amplifier further includes (i) a third gain block (G3) configured to generate a high-gain single-ended signal based on a differential output (G2_OUTN, G2_OUTP) of the second gain block (G2), and (ii) a fourth gain block (G4) configured to generate a low-gain single-ended signal based on a differential input (INP, INN) of the operational amplifier.

In a ninth possible implementation, the operational amplifier further includes a fifth gain block (G5) that is configured to combine the high-gain single-ended signal and the low-gain single-ended signal into a combined signal and couple the combined signal to an output (OUT) of the differential amplifier.

In a tenth possible implementation of the operational amplifier, the combined signal has a frequency response that is based on the high-gain single-ended signal at lower frequencies and is based on the low-gain single-ended signal at higher frequencies.

In an eleventh possible implementation of the operational amplifier, the first gain block (G1) and the second gain block (G2) are powered by the positive voltage (FP) and the negative voltage (FN), while the third gain block (G3), the fourth gain block (G4), and the fifth gain block (G5) are powered by the upper rail voltage (VDD) and the lower rail voltage (VSS).

In a twelfth possible implementation of the operational amplifier, the output of the operational amplifier (OUT) is coupled to the output of the second gain block (G2) via a compensation capacitor. The second gain block (G2) is configured to isolate the first gain block (G1) from the compensation capacitor.

In another aspect, the present disclosure generally describes an operational amplifier that includes a floating supply powered by a supply voltage ranging from an upper rail voltage (VDD) to a lower rail voltage (VSS). The floating supply is configured to receive a positive voltage (FP) corresponding to an input voltage of the operational amplifier and generate a negative voltage (FN) at a voltage below the positive voltage. The positive voltage (FP) and the negative voltage (FN) span a low voltage (LV) range that can float between the upper rail voltage and the lower rail voltage based on the input voltage (INN or INP) of the operational amplifier. The operational amplifier may be implemented according to any combination of the following possible implementations.

In a first possible implementation, the operational amplifier further includes a first gain block (G1) that is coupled to, and receives power from, the floating supply. The first gain block (G1) includes LV devices that receives a constant bias by the LV range that floats between the upper rail voltage (VDD) and the lower rail voltage (VSS) according to the input voltage of the operational amplifier.

In a second possible implementation of the operational amplifier, the first gain block (G1) includes a first LV transistor coupled at a gate to a positive input (INP) of the operational amplifier. The first gain block (G1) further includes a second LV transistor coupled at a gate to a negative input (INN) of the operational amplifier. A source of the first LV transistor and a source of the second LV transistor are directly connected to an upper common node, from which, the floating supply receives the positive voltage (FP). The first gain block (G1) further includes a first resistor coupled between the first LV transistor and a lower common node and a second resistor coupled between the second LV transistor and the lower common node. The first gain block (G1) further includes an upper current source coupled between the upper common node and the upper rail voltage (VDD).

In a third possible implementation of the operational amplifier, the floating supply includes an input transistor coupled at its gate to the upper common node of the first gain block (G1) to receive the positive voltage (FP) and coupled at its drain to the upper rail voltage (VDD) via a bias resistor. The floating supply further includes a voltage source coupled between a source of the input transistor and a lower common node to generate the negative voltage (FN) at the lower common node of the first gain block (G1). The floating supply further includes a lower current source coupled between the lower common node and the lower rail voltage (VSS).

In a fourth possible implementation, the floating supply further includes an amplifier configured to compare a voltage corresponding to the positive voltage (FP) to a reference voltage (VREF) corresponding to a threshold voltage of the input transistor. The floating supply further includes a clamping transistor coupled between the lower common node and the lower rail voltage (VSS). The clamping transistor is controlled by the amplifier so that when the voltage drops below the reference voltage (VREF), the negative voltage (FN) is coupled to the lower rail voltage (VSS).

In a fifth possible implementation, the operational amplifier includes a current mirror coupled to the upper rail voltage (VDD) via a first resistor and a second resistor.

In a sixth possible implementation of the operational amplifier, the voltage source of the floating supply is a diode-connected transistor.

In a seventh possible implementation of the operational amplifier, the voltage source of the floating supply is a resistor.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a schematic block diagram of an operational amplifier according to an implementation of the present disclosure.

FIG. 2 is a graph of the gain of the operational amplifier (opamp) versus frequency according to a possible implementation of the present disclosure.

FIG. 3 graphically illustrates the relationship between the floating voltage supply and the supply voltage according to a possible implementation of the present disclosure.

FIG. 4 is a schematic of a possible input stage for the operational amplifier of FIG. 1.

FIG. 5 is a schematic of a floating supply circuit for the operational amplifier of FIG. 1 according to a first possible implementation.

FIG. 6 graphically illustrates the relationship between the floating voltage supply and the supply voltage as an input voltage is decreased in four possible implementations of the present disclosure.

FIG. 7 graphically illustrates the relationship between the floating voltage supply and the supply voltage as the supply voltage is increased in four possible implementations of the present disclosure.

FIG. 8 is a schematic of a floating supply circuit for the operational amplifier of FIG. 1 according to a second possible implementation.

FIG. 9 is a schematic of a floating supply circuit for the operational amplifier of FIG. 1 according to a third possible implementation.

The components in the drawings are not necessarily to scale relative to each other. Like reference numerals designate corresponding parts throughout the several views.

### DETAILED DESCRIPTION

The present disclosure describes an operational amplifier (opamp) that can achieve high precision without using complicated chopping circuitry and without added trimming processes to match devices. An input offset voltage (i.e., offset voltage) of an operational amplifier (i.e., opamp) may contribute to the precision of the opamp. The offset voltage (V_{OS}) may be defined as a differential DC voltage between the positive and negative inputs of an opamp to produce zero voltage at the output. An opamp having an offset voltage closer to zero is more precise than an opamp having an offset voltage further from zero. The offset voltage may be described in terms of an average offset and an offset standard deviation for a population of devices manufactured in production. An opamp of the present disclosure may have an average offset voltage that is approximately zero (e.g., <2 μV) and a standard deviation (σ) on the order of 100 microvolt (e.g., 100 μV). A maximum offset voltage may be the offset voltage that a portion of a production lot is at or below. For example, an opamp of the present disclosure may have a maximum offset voltage that is less than one millivolt for 66 (i.e., 99.99966%) of the population (i.e., −1 mV≤6σ≤+1 mV) and can be considered a low offset voltage in the descriptions of the implementations that follow.

Transistors in an amplifier that are matched may be desirable for achieving a low offset voltage. For example, transistors having the same (i.e., equal) threshold voltages (V T) may be considered matched. Matching can improve for a circuit having larger devices (e.g., transistors). For example, transistors having a larger die area (i.e., larger transistors) may have less mismatch than transistors having a smaller die area (i.e., smaller transistors). Mismatches may arise due to variations in production that cause differences in the transistors. For example, a transistor may include a plurality of fingers (i.e., channels) that operate together. Mismatches can occur when these fingers are not exactly the same size and therefore operate differently. These differences tend to average out as the number of fingers increases. Accordingly, achieving higher precision may require transistors having a larger number of fingers, and this may correspond to a larger die area. For example, transistors may have ≥40 fingers with each finger having a channel length of 2-3 microns (m) and a channel width of 30-50 μm, and transistors having these dimensions can be considered large in the descriptions of implementations that follow.

Increasing the size of the transistors used in an opamp to improve a voltage offset may become impractical for higher voltages due to size constraints. For example, a maximum input voltage requirement for an opamp can place requirements on a minimum device size used for a transistor in the opamp in order to prevent damage. In particular, a high voltage transistor may require added separation between a drain and a gate. Thus, transistors designed for high voltages (i.e., HV transistors) can be larger than transistors designed for low voltages (i.e., LV transistors). A high voltage may be considered as a voltage above 5 volts and a low voltage may be considered as a voltage less than or equal to 5 volts. High voltage opamps may have an upper rail supply voltage (i.e., upper rail voltage) that is at or above the highest voltage expected at an input. For a rail-to-rail opamp a maximum input voltage may be approximately equal to the upper rail supply voltage (i.e., V_{DD}) of the opamp. The present disclosure describes an opamp that (i) has a low offset voltage and (ii) can accept a range of input voltages that includes high voltages. For example, in implementations referred to in the disclosure, the opamp can have a lower rail voltage (i.e., V_{SS}) that is equal to 0V (i.e., ground), an upper rail voltage (i.e., VDD) that is equal to 40V, and an input voltage (e.g., common mode voltage) that is a voltage in a range between the upper rail voltage and the lower rail voltage.

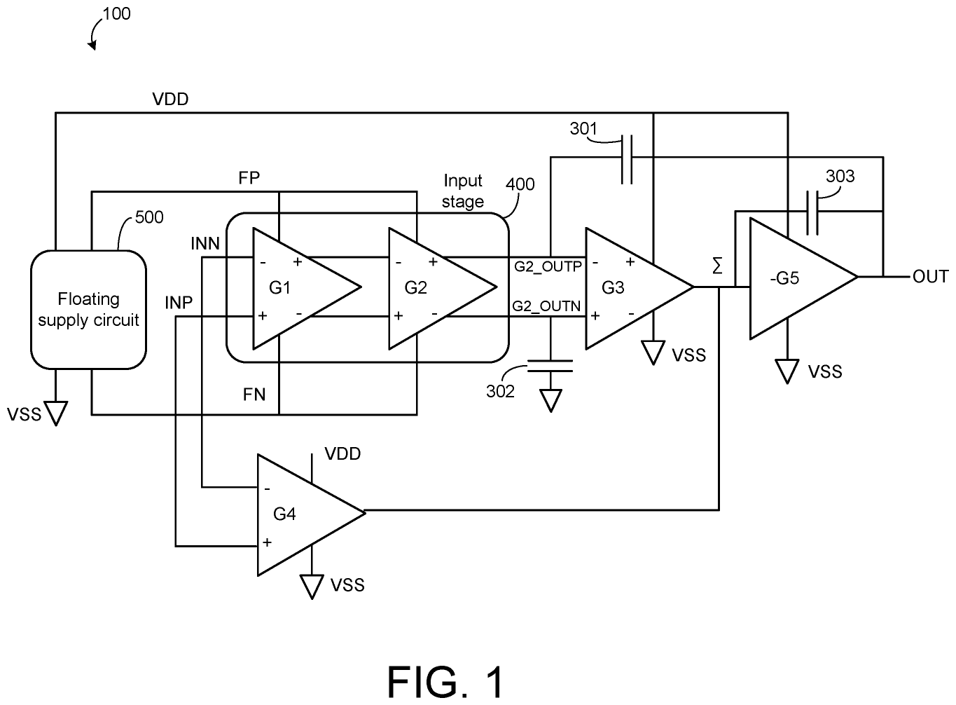

FIG. 1 is a schematic block diagram of an operational amplifier according to an implementation of the present disclosure. The opamp 100 includes an input stage 400 that has a low offset voltage and a high gain (e.g., V_{OUT}/V_{IN}). A high gain can be a gain greater than 1000 V/V. For the example implementations disclosed, the input stage can have an (overall) gain that is in a range of 3000≤G≤4000 V/V).

A high gain can make the input stage 400 the most significant source of offset voltage because the effects on the offset voltage from subsequent stages are reduced (e.g., divided) by the gain of the input stage 400. Accordingly, the offset voltage of the opamp 100 can be approximately equal to the offset voltage of the input stage 400.

High gain and low offset voltage may be difficult to achieve in one gain block. Accordingly, the opamp of the present disclosure has an input stage 400 that includes a first gain block (G1) and a second gain block (G2). The first gain block (G1) can be designed for precision (i.e., low offset voltage), while the second gain block (G2) can be designed for gain.

The first gain block (G1) and the second gain block (G2) may be inverting and therefore may include a pole that can affect a frequency response of the opamp. Accordingly, the opamp 100 includes at least one compensation capacitor 301 from the opamp output (OUT) to the input stage 400. Compensation capacitors 301, 302, 303 are included to provide unity gain stability to the opamp. In other words, the compensation capacitors 301, 302, 303 can improve the stability of the opamp 100. The second gain block (G2) may help to shield the first gain block from the compensation capacitors 301, 302.

The opamp 100 receives a positive input (INP) and a negative input (INN) (i.e., a differential input). The differential input (i.e., INP, INN) is coupled to two paths. In other words, the opamp is a two-path opamp. The two paths include a high-gain signal path and a low-gain signal path. The high-gain signal path (i.e., high-gain path) has a lower bandwidth (i.e., is slower) than the low-gain signal path (i.e., low-gain path), which has a higher bandwidth (i.e., is faster). The high-gain path includes the input stage 400 (i.e., G1, G2), a third gain block (G3) and a fifth gain block (G5). The third gain block can be configured to generate a high-gain single-ended signal based on a differential output (G2 OUTN, G2 OUTP) of the second gain block (G2). The low gain path includes a fourth gain block (G4) and the fifth gain block (G5). The fourth gain block can be configured to generate a low-gain single-ended signal based on a differential input (INP, INN) of the operational amplifier. A high-gain single-ended signal at the output of the third gain block (G3) is combined with a low-gain single-ended signal at the output of the fourth gain block (G4) at a summing node (E). The fifth gain block (G5) can be configured to (i) combine the high-gain single-ended signal and the low-gain single ended signal into a combined signal and (ii) couple the combined signal to the output (OUT) of the opamp 100. The combined signal can have an overall frequency response that is based on a frequency response of the high-gain single-ended signal and a frequency response of the low-gain single-ended signal.

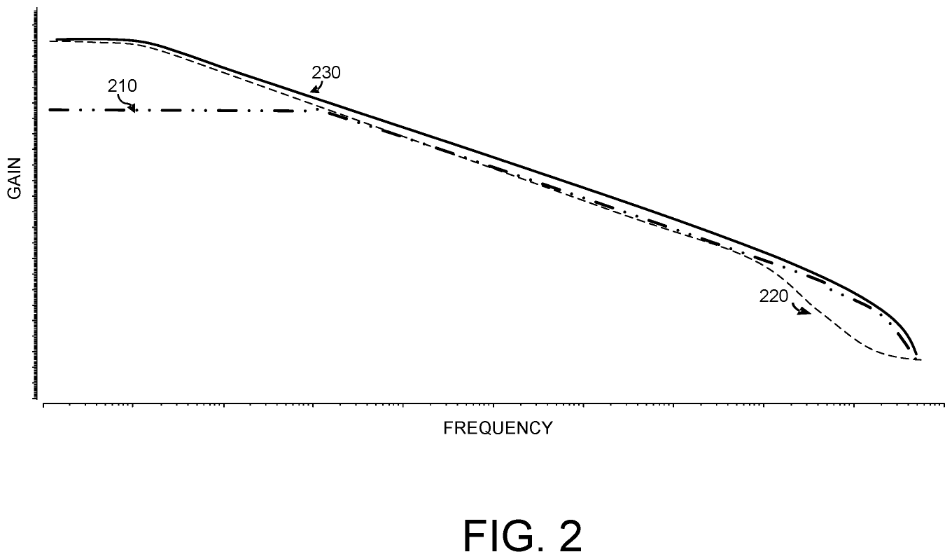

FIG. 2 is a graph of the gain of the opamp versus frequency according to a possible implementation of the present disclosure. There are three plots shown on the graph. A first plot is a low gain (high bandwidth) frequency response 210, a second plot is a high gain (low bandwidth) frequency response 220, and a third plot is the overall frequency response 230 of the opamp. The low gain frequency response 210 is the plot of the gain of the low gain path versus frequency. As shown, the high gain frequency response 220 has a gain that is higher than a gain of the low gain frequency response 210 at lower frequencies. Conversely the high gain frequency response 220 has a gain that is lower than a gain of the low gain frequency response 210 at higher frequencies. The reduction of the high gain frequency response 220 at high frequencies can be due to a pole in the response of the first gain block (G1). Combining the high gain path and the low gain path outputs results in an overall frequency response 230 for the opamp that has high gain at all frequencies. In other words, the combined signal can have a frequency response that is (i) based on (e.g., equal to) the high-gain single-ended signal at lower frequencies and (ii) based on (e.g., equal to) the low-gain single-ended signal at higher frequencies. In other words, combining the two paths can result in the opamp 100 having both high gain and high bandwidth because the overall frequency response is not influenced by the pole of the first gain block (G1).

Returning to FIG. 1, the first gain block (G1) and the second gain block (G2) are powered by a floating supply circuit (i.e., floating supply 500) that outputs a positive floating voltage (i.e., positive voltage (FP)) and a negative floating voltage (i.e., negative voltage (FN)). The positive voltage (FP) and the negative voltage (FN) may span a low-voltage (LV) (e.g., 1V FP-FN 5V). The third gain block (G3), the fourth gain block (G4) and the fifth gain block (G5) are powered by the power supply (i.e., supply) of the opamp. The supply of the opamp can be configured to output an upper rail voltage (VDD) and a lower rail voltage (V_{SS}). The upper rail voltage (VDD) and the lower rail voltage (V_{SS}) may span a high-voltage (HV) (e.g., 5 VDD-V_{SS}).

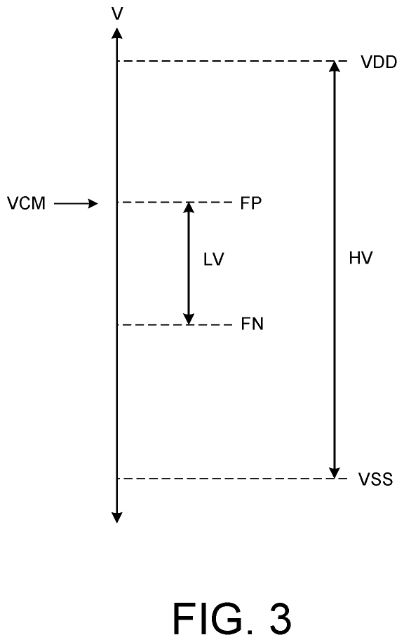

FIG. 3 graphically illustrates the relationship between the floating supply voltage (FP-FN) and the HV supply voltage (VDD-V_{SS}) according to a possible implementation of the present disclosure. The supply voltage can be used to power the third gain block (G3), the fourth gain block (G4), and the fifth gain block (G5). Accordingly, these gain blocks may use HV devices. The first gain block (G1) and the second gain block (G2) can be powered by the floating supply. Accordingly, these gain blocks may use LV devices. The floating supply can provide a constant bias to the LV devices despite variations in the fixed supply (i.e., supply). In some implementations, the supply (VDD-V_{SS}) includes high voltages. In these implementations, the floating supply also protects the LV devices from high voltages of the supply that could cause damage. The floating supply is configured to float according to an input voltage of the opamp so that the LV devices operate properly. For example, the positive voltage (FP) and the negative voltage (FN) can be set to values corresponding to the positive input (INP) and/or negative input (INP) so that the LV transistors of the first gain block (G1) and second gain block (G2) are in strong inversion for amplification. The positive voltage (FP) (or the negative voltage (FN)) can be set to a common mode voltage (VCM) of the input (INP, INN). The common mode voltage may be defined in any way to ensure operation of the LV devices without damage. The LV range between the positive voltage (FP) and the negative voltage (FN) may be fixed. Likewise, the HV range between the upper rail voltage (VDD) and the lower rail voltage (V_{SS}) may be fixed. The positive voltage (FP) and the negative voltage (FN) may float between the upper rail voltage (VDD) and the lower rail voltage (V_{SS}) according to the common mode voltage (VCM) of the input. For example, if the common mode voltage (VCM) increases by a volt, then the positive voltage (FP) increases by a volt and the negative voltage (FN), which is relative to the positive voltage, increases by a volt. This shift of the LV range according to the input voltage is referred to as floating.

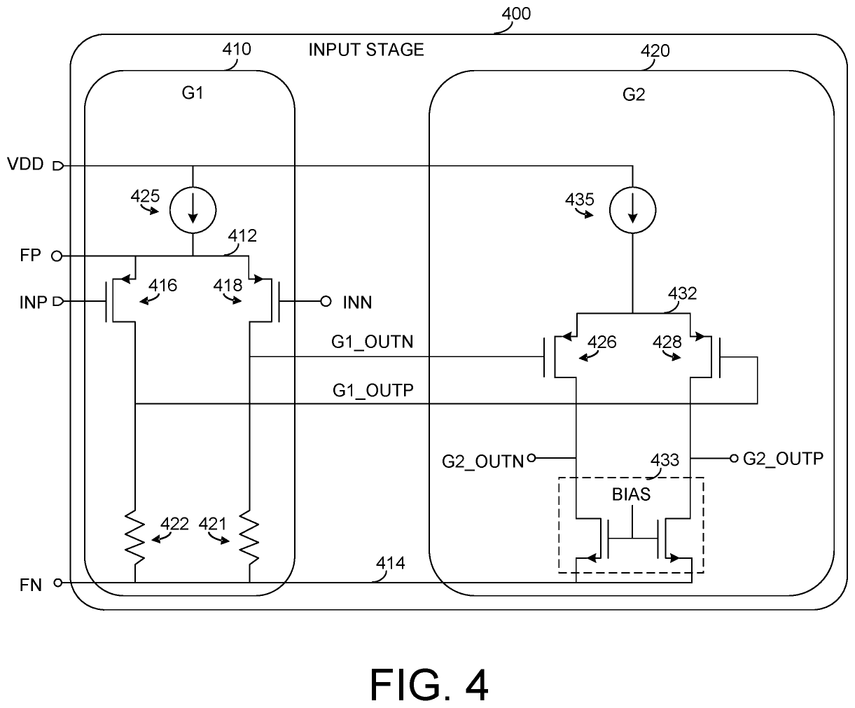

FIG. 4 illustrates a possible input stage for the operational amplifier of FIG. 1. The input stage 400 includes a first gain block 410 (G1). The first gain block 410 includes a first differential pair of low voltage transistors. The first LV differential pair includes a first LV transistor 416 coupled at a controlling terminal (e.g., gate terminal) to the positive input (INP) of the operational amplifier. The first LV differential pair further includes a second LV transistor 418 coupled at a controlling terminal (e.g., gate terminal) to the negative input (INN) of the operational amplifier. As shown, the first LV transistor 416 and the second LV transistor 418 are implemented as PMOS transistors. The first LV transistor and the second LV transistor are coupled to each other at their source terminals (i.e., have a common source) and are biased by a first upper current source 425 that is coupled between the upper rail voltage (VDD) and the common source. The common source forms what will be referred to as the upper common node 412.

The positive voltage FP is the voltage formed at the upper common node by current flowing through a conducting transistor of the first differential pair. If the positive input voltage (INP) is greater than the negative input voltage (INN), then the second LV transistor 418 will conduct and the positive voltage (FP) will be the negative input voltage (INN) plus a gate-to-source voltage (VGs) of the second LV transistor 418. If, on the other hand, the positive input voltage (INP) is less than the negative input voltage (INN), then the first LV transistor 416 will conduct and the positive voltage (FP) will be the positive input voltage (INP) plus a gate-to-source voltage (VGS) of the first LV transistor 416. Thus, the common mode voltage (VCM) of the input may be defined by the equation below.

VCM=min(INP,INN)+VGS (1)

The first LV transistor 416 and the second LV transistor 418 may be matched to provide a low offset voltage because they are low voltage devices. The low voltage devices are protected from being damaged by the HV upper rail voltage by the first upper current source 425, which drops any voltage between the upper rail voltage (VDD) and the upper common node 412 voltage (i.e., FP).

A gain of the first gain block 410 may be set by a resistance between the first LV differential pair and a lower common node 414. The resistance is provided by (i) a first resistor 422 coupled between a drain of the first LV transistor 416 and the lower common node 414 and (ii) a second resistor 421 coupled between a drain of the second LV transistor 418 and the lower common node 414. The resistors 422, 421 may be matched (e.g., equal resistance) so that the current through each transistor 416, 418 in the first LV differential pair is matched to provide a low offset voltage. The matching precision may be based on a type of resistor used. For example, thin film resistors may be used to provide more precision than a polysilicon resistor. Either type may be used in the first gain block 410 (G1).

The first gain block 410 (G1) can provide a low offset voltage for a few reasons. First, the size of the LV transistors in the input differential pair can be made relatively large in a die area compared to a size of HV transistors in the same die area. Second, the discrete resistors of the first gain block can be made very accurately compared to other resistor types, such as active resistors.

The use of an LV transistor may offer additional advantages as well. For example, LV transistor have a higher transconductance gain than HV transistors. Noise (e.g., thermal noise) at the input of the opamp may be reduced (e.g., divided) by the transconductance (gm) of the LV gain blocks. When the transconductance gain is higher this noise is lower (e.g., 70 nV/\sqrt{HZ})@ 10 Hz). Further flicker noise may be lower (e.g., 1.6 μVpp for 0.1 Hz to 10 Hz) in LV transistors than high voltage transistors. Noise and voltage offset at the input of the opamp from later gain blocks may be reduced by the gain of the first gain block 410. Accordingly, the first gain block can be the main contributor to noise and offset voltage.

The gain of the first gain block 410 (G1) is limited, however, by a maximum resistance of the first resistor 422 and the second resistor 421. Increasing the resistance to increase gain also raises the drain voltage on the transistors. An increase of the drain voltage could change the operating states (e.g., saturation) of the first LV transistor 416 and/or the second LV transistor 418 for a low input voltage. Accordingly, the value of this resistance may be relatively low, thereby limiting the gain of the first gain block 410 (G1).

As shown in FIG. 4, the input stage 400 further includes a second gain block 420 (G2). The first gain block 410 (G1) generates a first voltage offset and amplifies with a first gain. The second gain block 420 (G2) generates a second voltage offset and amplifies with a second gain. The first and second voltage offsets are generated intrinsically based on the physically properties of the first and second gain blocks respectively, as described previously. The first voltage offset can be (e.g., is designed to be) less than the second voltage offset. The second gain can be (e.g., is designed to be) greater than the first gain. Accordingly, the first gain block 410 (G1) and the second gain block 420 (G2) can be configured as an input stage 400 that provides both low offset voltage and high gain.

The second gain block 420 (G2) includes a second LV differential pair. The second LV differential pair includes a third LV transistor 426 coupled and a fourth LV transistor 428. For the implementation shown in FIG. 4, the third LV transistor 426 and the fourth LV transistor 428 are PMOS transistors. A gate of the third LV transistor 426 is coupled to the drain of the second LV transistor 418, which serves as a negative output (G1_OUTN) of the first gain block 410 (G1). A gate of the fourth LV transistor 428 is coupled to the drain of the first LV transistor 416, which serves as a positive output (G1_OUTP) of the first gain block 410 (G1). The third LV transistor 426 and the fourth LV transistor 428 are coupled to each other at their source terminals (i.e., have a common source) and are biased by a second upper current source 435 that is coupled between the upper rail voltage (VDD) and the common source. The common source forms what will be referred to as the common source node 432. The low voltage devices are protected from being damaged by the HV upper rail voltage by the second upper current source 435, which drops any voltage between the upper rail voltage (VDD) and a voltage at the common source node 432.

A gain of the second gain block 420 may be set by a resistance between the second LV differential pair and the lower common node 414. The resistance is provided by an active resistance 433 coupled between the drains of the third LV transistor 426 and the fourth LV transistor 428 and the lower common node 414. The active resistance 433 is configured to receive a bias signal (BIAS) to control its resistance. The resistance may be made relatively large (e.g., R>10 MΩ) so that the gain of the second gain block 420 is relatively large. The second upper current source can maintain the proper voltage at the common source node 432 for amplification even when the active resistance is very large. A negative output (G2 OUTN) of the second gain block 420 (G2) is at the drain of the third LV transistor 426, and positive output (G2 OUTP) of the second gain block 420 (G2) is at the drain of the fourth LV transistor 428. The output of the second gain block 420 (G2) is differential and inverted from its input.

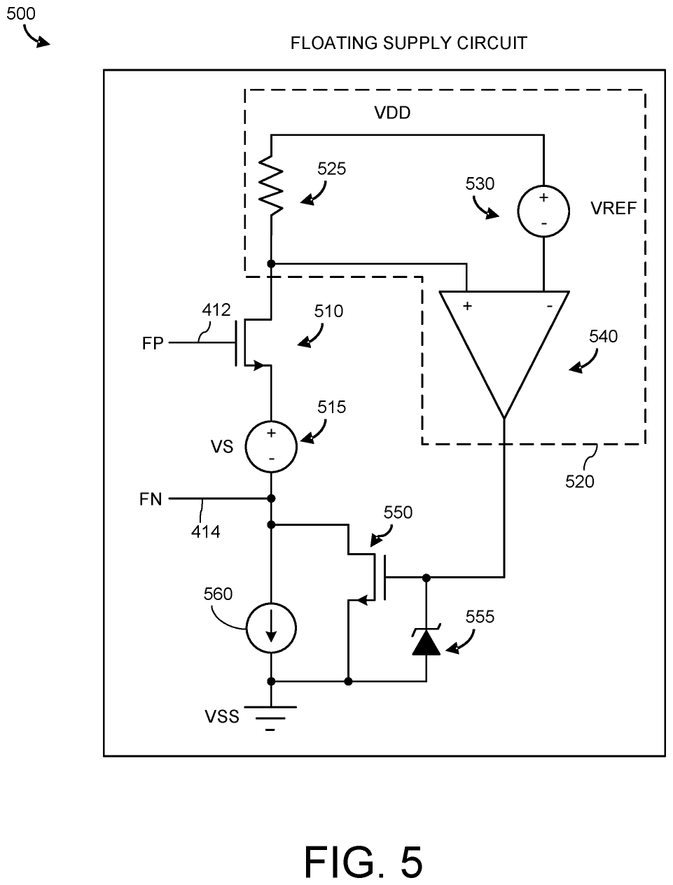

FIG. 5 is a schematic of a floating supply circuit for the operational amplifier of FIG. 1 according to a first possible implementation. The floating supply circuit (i.e., floating supply 500) is powered by the upper rail voltage (VDD) and the lower rail voltage (VSS) of the HV power supply. The floating supply 500 includes an input transistor 510. As shown, the input transistor 510 can be an NMOS transistor. The input transistor 510 is coupled at its gate to the upper common node 412 of the first gain block 410. Accordingly, the positive voltage (FP), at the upper common node 412, is received at the gate of the input transistor 510. The input transistor 510 is coupled at its drain to the upper rail voltage (VDD) via a bias resistor 525 and is coupled at its source to a voltage source 515 (VS). The voltage source 515 can be set to a LV. The negative voltage (FN) generated at the lower common node 414 is given by the equation below.

FN=FP−VGS−VS (2)

In the equation above VGS is the gate to source voltage of the input transistor 510 and VS is the voltage of the voltage source, which can be in the LV range (e.g., 3-5V). The positive voltage (FP) is received at the floating supply 500 from the input stage 400. The negative voltage (FN) is transmitted from the floating supply 500 to the input stage 400.

The floating supply 500 further includes a lower current source 560 coupled between the lower common node 414 and the lower rail voltage (VSS) (e.g., ground). The lower current source 560 is configured to sink the current from the input stage 400 just as first upper current source 425 and second upper current source 435 are configured to source current to the input stage.

The floating supply 500 further includes a sensor circuit 520 configured to sense a voltage corresponding to the positive voltage (FP) and output a signal when the voltage satisfies a criterion. The sensor circuit 520 can be configured to sense when the positive voltage (FP) drops low enough for the input transistor to stop conducting (i.e., turns OFF). To sense this condition, the sensor circuit 520 can compare the voltage across the bias resistor 525 (which corresponds to the positive voltage (FP)) to a reference voltage (VREF) from a reference source 530 (which corresponds to a threshold voltage of the input transistor). The sensor circuit 520 is further configured to compare the voltage corresponding to the positive voltage (FP) to the reference voltage (VREF) corresponding to the threshold voltage of the input transistor and to control a clamping transistor 550 ON or OFF according to the comparison.

The bias resistor 525 of the sensor circuit 520 is coupled between the drain of the input transistor 510 and the upper rail voltage (VDD). The bias resistor generates a voltage based on the positive voltage (FP) coupled to the input transistor 510. The sensor circuit further includes a reference source 530 to generate the reference voltage (VREF) and an amplifier 540 configured to compare the voltage on the bias resistor 525 to the reference voltage 530 and output a signal to control a clamping transistor 550. The clamping transistor 550 can be turned ON to couple the lower common node 414 to the lower rail voltage (VSS) (e.g., ground) when the input voltage (FP) is too low to properly control the negative voltage (FN). In other words, the clamping transistor can be turned ON to pull the negative voltage (FN) towards the lower rail voltage (VSS) when the input transistor turns OFF. Otherwise, the negative voltage (FN) would float because the input transistor and the voltage source (VS) do not control this sufficiently when the input transistor 510 turns OFF.

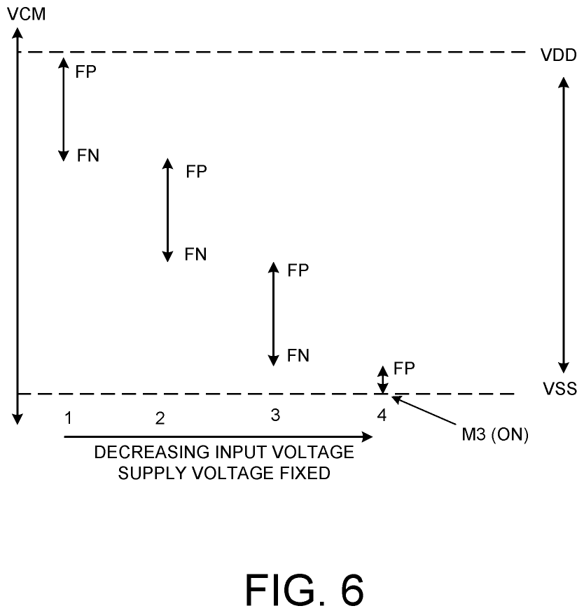

FIG. 6 graphically illustrates the relationship between the floating voltage supply and the supply voltage as an input voltage (e.g., FP) is decreased. The graph shows four possible cases. In the first case (1), the positive voltage (FP) is close to the upper rail voltage (VDD) and the span between positive voltage (FP) and the negative voltage (FN) (i.e., FP-FN) is the floating supply voltage given in the equation above (e.g., see Equation (2)). In the second case (2), the input voltage (INP) is reduced, making the positive voltage (FP) lower. The floating supply voltage (FP-FN) is the same but is shifted according to the shift in the positive voltage. In the third case (3), the input voltage (INP) is further reduced making the positive voltage (FP) even lower. The floating supply voltage (FP-FN) is the same but is shifted down according to the shift in the positive voltage. In the fourth case (4), the input voltage (INP) is further reduced making the positive voltage (FP) even lower. In the fourth case the positive voltage (FP) is below the reference voltage. As a result, the negative voltage is clamped at, or near, the lower supply rail (VSS). In the floating supply 500, this is accomplished by turning the clamping transistor ON to couple (e.g., short) the lower common node 414 to the lower rail voltage. This clamping can prevent the negative voltage (FN) from floating and can extend (e.g., maximize) the span (FP-FN) of the floating supply in the low input voltage condition. The clamping transistor 550 also helps to sink current as the negative voltage FN becomes close to the lower rail voltage (VSS).

In a possible implementation, the floating supply 500 further includes a Zener diode coupled between the gate of the clamping transistor 550 and the lower rail voltage (VSS). the Zener diode can set the maximum voltage that can appear on the clamping transistor 550 for protection.

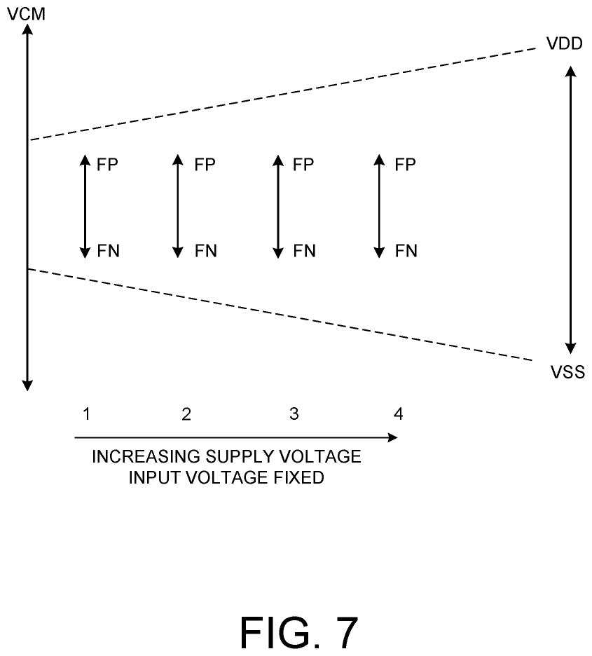

FIG. 7 graphically illustrates the relationship between the floating voltage supply and the supply voltage as the supply voltage is increased in four possible implementations of the present disclosure. The graph shows four cases. In each case (1,2,3,4) the supply voltage is increased while the input voltage (e.g., FP) is held constant. As shown, the floating supply voltage (FP-FN) is unaffected by changes to the supply voltage. Accordingly, floating supply allows the input stage 400 to have a power supply rejection ratio (PSRR) that is high (e.g., >130 dB).

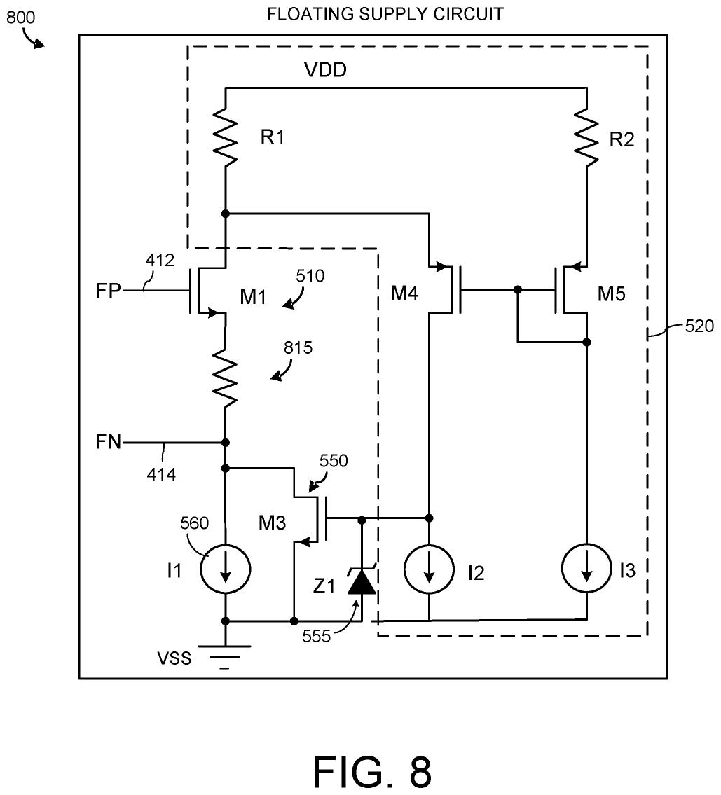

FIG. 8 is a schematic of a floating supply circuit for the operational amplifier of FIG. 1 according to a second possible implementation. The floating supply circuit (i.e., floating supply 800) is similar to the implementation shown in FIG. 5. The floating supply 800 includes an input transistor 510 coupled at its gate terminal to the upper common node 412 so that it is controlled by the positive voltage (FP). The floating supply 800 further includes a lower current source 560 coupled to a lower common node 414, and a clamping transistor 550 that can be controlled to clamp the negative voltage (FN) to the lower rail voltage (VSS) when the positive voltage (FP) becomes too low for the input transistor 510 to operate properly. The floating supply 800 includes a sensor circuit 520 configured to compare a voltage corresponding to the positive voltage (FP) to a threshold and to turn the clamping transistor 550 ON when the voltage satisfies a criterion (e.g., crosses a threshold). In the implementation shown, the sensor circuit 520 include a current mirror (M4, M5) fed by a pair of matched current sources (12, 13). The gate voltage of the clamping transistor 550 is determined by the voltage difference between the resistors R1 and R2. The voltage source fixing the voltage between the upper common node 412 and the lower common node 414 is implemented with a resistor 815 in the implementation shown.

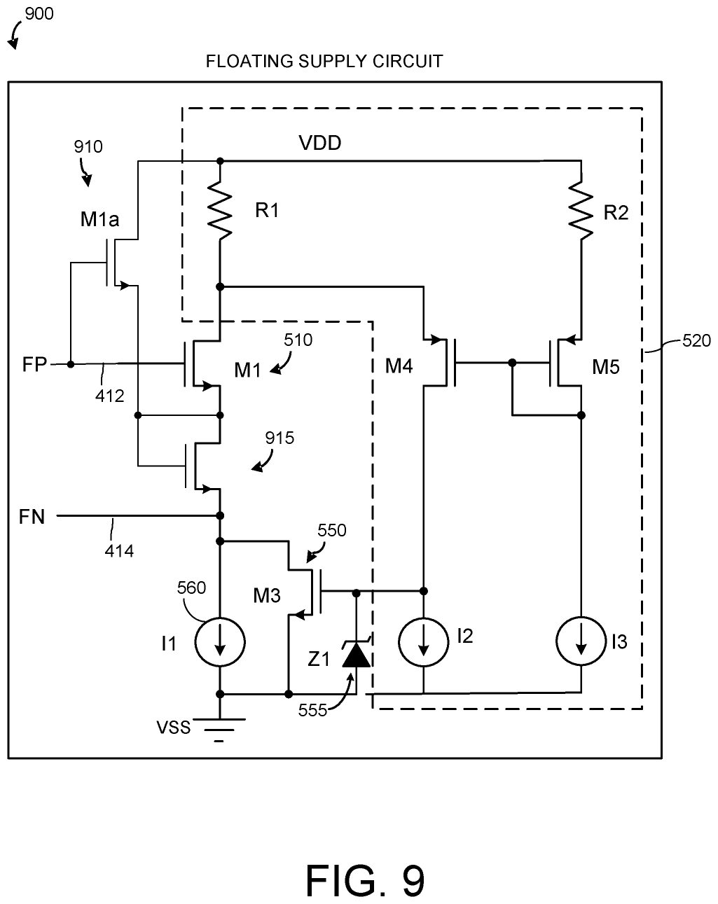

FIG. 9 is a schematic of a floating supply circuit for the operational amplifier of FIG. 1 according to a third possible implementation. The floating supply circuit (i.e., floating supply 900) is similar to the implementation shown in FIG. 8. The floating supply 900 includes an input transistor 510 coupled at its gate terminal to the upper common node 412 so that it is controlled by the positive voltage (FP). The floating supply 800 further includes a lower current source 560 coupled to a lower common node 414, and a clamping transistor 550 that can be controlled to clamp the negative voltage (FN) to the lower rail voltage V_{SS} when the positive voltage (FP) becomes too low for the input transistor 510 to operate properly (e.g., the input transistor turns OFF). The floating supply 900 includes a sensor circuit 520 configured to compare a voltage corresponding to the positive voltage (FP) to a threshold and to turn the clamping transistor 550 ON when the voltage satisfies a criterion (e.g., crosses a threshold). In the implementation shown, the sensor circuit 520 includes a current mirror (M4, M5) fed by a pair of matched current sources (12, 13). The gate voltage of the clamping transistor 550 is determined by the voltage difference between the resistors R1 and R2. The voltage source of the floating supply 900 circuit is implemented with a diode connected transistor 915 that is biased with a bias transistor 910 (M1a).

In the specification and/or figures, typical embodiments have been disclosed. The present disclosure is not limited to such exemplary embodiments. For example, variations may be conceived by replacing PMOS transistors with NMOS transistors in complementary circuits, and vice versa. Additionally, various implementations of the voltage sources or the current sources shown in the circuits are within the scope of the present disclosure.

The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

1. An operational amplifier comprising:
an input stage including:
a first gain block including a first low voltage (LV) differential pair having a first voltage offset and a first gain; and
a second gain block including a second LV differential pair having a second voltage offset and a second gain, the first voltage offset being less than the second voltage offset and the second gain being greater than the first gain; and
a floating supply powered by a supply voltage ranging from an upper rail voltage to a lower rail voltage, the floating supply configured to output a floating supply voltage ranging from a positive voltage to a negative voltage, the floating supply voltage floating according to an input of the operational amplifier and providing power to the input stage.

2. The operational amplifier according to claim 1, wherein the first LV differential pair and the second LV differential pair are isolated from the upper rail voltage and the lower rail voltage by the floating supply.

3. The operational amplifier according to claim 1, wherein the floating supply receives the positive voltage from an upper common node of the first gain block and generates a negative voltage at a lower common node of the first gain block and the second gain block.

4. The operational amplifier according to claim 3, wherein the first gain block includes:
a first LV transistor coupled at a gate to a positive input of the operational amplifier;
a second LV transistor coupled at a gate to a negative input of the operational amplifier, a source of the first LV transistor and a source of the second LV transistor directly connected to the upper common node;
a first resistor coupled between a drain of the first LV transistor and the lower common node, a positive output of the first gain block at the drain of the first LV transistor;
a second resistor coupled between a drain of the second LV transistor and the lower common node, a negative output of the first gain block at the drain of the second LV transistor; and
a first upper current source coupled between the upper rail voltage and the upper common node.

5. The operational amplifier according to claim 4, wherein the positive voltage at the upper common node of the first gain block is the lower of the positive input and the negative input plus a gate to source voltage of the first LV transistor or the second LV transistor.

6. The operational amplifier according to claim 3, wherein the second gain block includes:
a third LV transistor coupled at its gate to a negative output of the first gain block;
a fourth LV transistor coupled at its gate to a positive output of the first gain block, a source of the fourth LV transistor directly coupled to a source of the third LV transistor at a common source node;
a second upper current source coupled between the upper rail voltage and the common source node; and
an active load that is:
coupled between a drain of the third LV transistor and the lower common node, a negative output of the second gain block at the drain of the third LV transistor, and
coupled between a drain of the fourth LV transistor and the lower common node, a positive output of the second gain block at the drain of the fourth LV transistor.

7. The operational amplifier according to claim 3, wherein the floating supply includes:
an input transistor coupled at its gate to the upper common node of the first gain block to receive the positive voltage and coupled at its drain to the upper rail voltage via a bias resistor;
a voltage source coupled between a source of the input transistor and the lower common node to generate the negative voltage at the lower common node of the first gain block and the second gain block; and
a lower current source coupled between the lower common node and the lower rail voltage.

8. The operational amplifier according to claim 7, wherein the floating supply further includes:
an amplifier configured to compare a voltage corresponding to the positive voltage to a reference voltage corresponding to a threshold voltage of the input transistor; and
a clamping transistor coupled between the lower common node and the lower rail voltage, the clamping transistor controlled by the amplifier so that when the voltage drops below the reference voltage, the negative voltage is coupled to the lower rail voltage.

9. The operational amplifier according to claim 1, further including:
a third gain block configured to generate a high-gain single-ended signal based on a differential output of the second gain block; and
a fourth gain block configured to generate a low-gain single-ended signal based on a differential input of the operational amplifier.

10. The operational amplifier according to claim 9, further comprising a fifth gain block configured to:
combine the high-gain single-ended signal and the low-gain single-ended signal into a combined signal; and
couple the combined signal to an output of the operational amplifier.

11. The operational amplifier according to claim 10, wherein the combined signal has a frequency response that is based on the high-gain single-ended signal at lower frequencies and is based on the low-gain single-ended signal at higher frequencies.

12. The operational amplifier according to claim 10, wherein:
the first gain block and the second gain block are powered by the positive voltage and the negative voltage; and
the third gain block, the fourth gain block, and the fifth gain block are powered by the upper rail voltage and the lower rail voltage.

13. The operational amplifier according to claim 9, wherein:
the output of the operational amplifier is coupled to the output of the second gain block via a compensation capacitor, the second gain block configured to isolate the first gain block from the compensation capacitor.

14. An operational amplifier, comprising:
a floating supply powered by a supply voltage ranging from an upper rail voltage to a lower rail voltage, the floating supply configured to:
receive a positive voltage corresponding to an input voltage of the operational amplifier, and
generate a negative voltage at a voltage below the positive voltage, the positive voltage and the negative voltage spanning a low voltage range that floats between the upper rail voltage and the lower rail voltage based on the input voltage of the operational amplifier.

15. The operational amplifier according to claim 14, further comprising:
a first gain block that is coupled to, and receives power from, the floating supply, the first gain block including LV devices that receive a constant bias in the low voltage range that floats between the upper rail voltage and the lower rail voltage according to the input voltage of the operational amplifier.

16. The operational amplifier according to claim 15, wherein the first gain block includes:
a first LV transistor coupled at a gate to a positive input of the operational amplifier;
a second LV transistor coupled at a gate to a negative input of the operational amplifier, a source of the first LV transistor and a source of the second LV transistor directly connected to an upper common node, the floating supply receiving the positive voltage from the upper common node,
a first resistor coupled between the first LV transistor and a lower common node;
a second resistor coupled between the second LV transistor and the lower common node; and
an upper current source coupled between the upper common node and the upper rail voltage.

17. The operational amplifier according to claim 16, wherein the floating supply includes:
an input transistor coupled at its gate to the upper common node of the first gain block to receive the positive voltage and coupled at its drain to the upper rail voltage via a bias resistor;
a voltage source coupled between a source of the input transistor and the lower common node to generate the negative voltage at the lower common node of the first gain block; and
a lower current source coupled between the lower common node and the lower rail voltage.

18. The operational amplifier according to claim 17, wherein the floating supply further includes:
an amplifier configured to compare a voltage corresponding to the positive voltage to a reference voltage corresponding to a threshold voltage of the input transistor; and
a clamping transistor coupled between the lower common node and the lower rail voltage, the clamping transistor controlled by the amplifier so that when the voltage drops below the reference voltage, the negative voltage is coupled to the lower rail voltage.

19. The operational amplifier according to claim 18, wherein the amplifier includes a current mirror coupled to the upper rail voltage via a third resistor and a fourth resistor.

20. The operational amplifier according to claim 17, wherein the voltage source is a diode-connected transistor.

21. The operational amplifier according to claim 17, wherein the voltage source is a resistor.
